(19) United States
(12) Patent Application Publication
(10) Pub. No.: US 2015/0028726 A1
(43) Pub. Date: Jan. 29, 2015

(54) PIEZOELECTRIC SHEET, PIEZOELECTRIC DEVICE INCLUDING THE SAME, AND METHOD OF FABRICATING PIEZOELECTRIC DEVICE

(71) Applicant: SAMSUNG ELECTRO-MECHANICS CO., LTD., Suwon (KR)

(72) Inventors: Boum Seock Kim, Suwon (KR); Jung Wook Seo, Suwon (KR)

(73) Assignee: SAMSUNG ELECTRO-MECHANICS CO., LTD., Suwon (KR)

(21) Appl. No.: 14/168,875

(22) Filed: Jan. 30, 2014

(30) Foreign Application Priority Data
Jul. 29, 2013 (KR) 10-2013-0089770

(51) Int. Cl. H01L 41/047; H01L 41/333; H01L 41/277

(52) U.S. Cl. CPC H01L 41/0474; H01L 41/277; H01L 41/333
USPC 310/365; 428/446; 428/704; 252/62.9 R; 156/242

(57) ABSTRACT

There is provided a piezoelectric device, including a laminated body in which a plurality of piezoelectric sheets including a first piezoelectric substance having a single crystal structure and a second piezoelectric substance having a polycrystalline structure are laminated, first and second internal electrodes interposed between the piezoelectric sheets and alternating so as to have different polarities in a laminated direction, and first and second external electrodes formed on one surface of the laminated body to be electrically connected to the first and second internal electrodes, wherein the first piezoelectric substance has an aspect ratio (d/l) of 1/8 to 1/4.

### CROSS-REFERENCE TO RELATED APPLICATIONS

This application claims the priority of Korean Patent Application No. 10-2013-0089770 filed on Jul. 29, 2013, in the Korean Intellectual Property Office, the disclosure of which is incorporated herein by reference.

### BACKGROUND

The present disclosure relates to a piezoelectric sheet, a piezoelectric device including the same, and a method of fabricating a piezoelectric device.

Recently, in portable electronic devices such as portable phones, game machines, e-book readers, and the like, vibrations have been used as a signal silently notifying a user of a call reception, or in a touch type device allowing for a user to touch the portable electronic device to thereby input data thereto, vibrations have been used as a signal providing feedback to the user.

As an apparatus generating vibrations, a piezoelectric device having a response speed faster than that of an existing vibration motor and capable of being driven at various frequencies has been used.

Such a piezoelectric device, a device using the piezoelectric effect, is a device in which electrical polarization occurs to generate a potential difference when external force is applied thereto, or, on the other hand, deformation or deformative force is generated when voltage is applied thereto.

A piezoelectric device, also referred to as a piezoelectric element, is fabricated using a material such as a crystal, tourmaline, Rochelle salts, barium titanate, monoammonium phosphate, tartaric acid ethylene diamine, or the like, having excellent piezoelectric properties.

The piezoelectric device used as a vibration generating device may generate vibrations using deformation or deformative force generated by applying voltage to a piezoelectric substance.

In order to increase the deformation or the deformative force generated in the piezoelectric device, a plurality of thin piezoelectric layers having an internal electrode formed thereon may be laminated to thereby provide stronger vibrations.

That is, in the case of a piezoelectric device fabricated by laminating the plurality of thin piezoelectric layers having the internal electrode formed thereon, when the voltage is applied thereto, structural deformation may be caused by a dipole in the piezoelectric layer generated due to the formation of an electric field between two electrodes.

Mechanical displacement may be generated by the structural deformation, thereby generating vibrations.

Since the displacement of the piezoelectric device is increased in proportion to the electric field, a higher level of voltage needs to be applied to the electrodes in order to obtain greater degrees of displacement.

In general, since the higher level of voltage generated to be used as an operating voltage may cause a problem in terms of a circuit, the piezoelectric device is typically fabricated in a form in which a plurality of piezoelectric layers are laminated and a thickness of the layer between the electrodes is decreased, such that a larger electric field may be applied to the electrode at the same level of voltage, thereby generating greater degrees of displacement.

For example, in comparing a case in which the same level of voltage is applied to a piezoelectric device formed of one layer with a case in which the same level of voltage is applied to the piezoelectric device formed by laminating a plurality of layers, the piezoelectric device formed by laminating the plurality of layers may generate a greater degree of displacement than the piezoelectric device formed of one layer at the same level of voltage.

In order to obtain greater degrees of displacement under the same level of voltage, a material having a higher d31 value, a piezoelectric constant, needs to be used.

In a case of using a piezoelectric material having a commonly-used polycrystalline structure, the d31 value may be approximately 200 pC/N.

The piezoelectric material having the polycrystalline structure has a very small d31 value as compared to a piezoelectric material having a single crystal structure when the voltage is applied in a 3-direction, wherein the d31 value is proportional to a displacement in a 1-direction.

The piezoelectric material having a single crystal structure has the d31 value of about 2000 pC/N, a value larger 10 times or more than that of the piezoelectric material having the polycrystalline structure.

Since the piezoelectric material having the single crystal structure has the crystal structure aligned in one direction, the displacement may be only generated in one direction.

However, the manufacturing of a piezoelectric material having such a single crystal structure may be difficult and costs required therefor may be high. In addition, the piezoelectric material having such a single crystal structure may have poor durability and may be easily broken as compared to the piezoelectric material having the polycrystalline structure.

Therefore, in order to have a high degree of displacement, a piezoelectric material having the high d31 value, ease of fabrication and excellent durability is in demand.

In addition, in order to have higher displacement, the thickness of the piezoelectric layer interposed between the internal electrodes may be reduced.

As the thickness of the piezoelectric layer is reduced, a metal of the internal electrode may move through a grain boundary of the piezoelectric layer when an electric field is applied, thereby causing a short-circuit.

Such a short-circuit is on the rise as a main factor in decreasing reliability of the piezoelectric devices.

Therefore, a method capable of preventing the phenomenon in which the metal moves through the grain boundary is demanded.

Patent Document 1 of the following related art document relates to a piezoelectric actuator for driving a haptic device.

Specifically, the disclosure described in Patent Document 1 relates to a piezoelectric actuator for driving a haptic device, including a piezoelectric substance in which a plurality of piezoelectric layers having the same polling direction are laminated, and an electrode pattern formed on the piezoelectric substance, wherein the piezoelectric layer has a length greater than or equal to four times a width of the piezoelectric layer and has a width greater than or equal to ten times a thickness of the piezoelectric layer.

The piezoelectric actuator disclosed in Patent Document 1 does not include a single crystal piezoelectric material or a polycrystalline piezoelectric material.

Further, it does not disclose an aspect ratio (d/l) of the single crystal piezoelectric material.

### RELATED ART DOCUMENT

(Patent Document 1) Korean Patent Laid-Open Publication No. 2012-0013273

### SUMMARY

An aspect of the present disclosure may provide a piezoelectric sheet having a high d31 value and excellent durability.

An aspect of the present disclosure may also provide a piezoelectric device having improved reliability by preventing a phenomenon in which metal atoms in an internal electrode move through a grain boundary due to thinness of the piezoelectric sheet, and a method of fabricating the piezoelectric device.

According to an aspect of the present disclosure, a piezoelectric sheet may include: a first piezoelectric substance having a single crystal structure; and a second piezoelectric substance having a polycrystalline structure, wherein the first piezoelectric substance has an aspect ratio (d/l) of 1/8 to 1/4.

The piezoelectric sheet may further include a piezoelectric shell enclosing the first piezoelectric substance.

The piezoelectric shell may have a crystal direction the same as that of the first piezoelectric substance.

The piezoelectric shell may have a d31 value of 200 pC/N to 700 pC/N.

The first piezoelectric substance may have a content of 3% to 30%.

According to another aspect of the present disclosure, a piezoelectric device may include: a laminated body in which a plurality of piezoelectric sheets including a first piezoelectric substance having a single crystal structure and a second piezoelectric substance having a polycrystalline structure are laminated; first and second internal electrodes interposed between the piezoelectric sheets and alternating so as to have different polarities in a laminated direction; and first and second external electrodes formed on one surface of the laminated body to be electrically connected to the first and second internal electrodes, wherein the first piezoelectric substance has an aspect ratio (d/l) of 1/8 to 1/4.

The piezoelectric device may further include a piezoelectric shell enclosing the first piezoelectric substance.

The piezoelectric shell may have a crystal direction the same as that of the first piezoelectric substance.

The piezoelectric shell may have a d31 value of 200 pC/N to 700 pC/N.

The first piezoelectric substance may have a content of 3% to 30%.

The piezoelectric device may further include a vibrating plate attached to a bottom surface of the laminated body.

According to another aspect of the present disclosure, a method of fabricating a piezoelectric device may include: preparing a first piezoelectric substance having a single crystal structure and a second piezoelectric substance having a polycrystalline structure; mixing the first and second piezoelectric substances; preparing a plurality of green sheets by compressing the mixed first and second piezoelectric substances; printing first and second internal electrodes on the green sheets using a conductive paste; preparing a laminated body by laminating and compressing the green sheets having the first and second internal electrodes printed thereon; and performing a heat-treatment on the laminated body, wherein the first piezoelectric substance has an aspect ratio (d/l) of 1/8 to 1/4.

By the performing of the heat-treatment, a piezoelectric shell enclosing the first piezoelectric substance may be formed.

The heat-treatment may be performed at a temperature of 0.5 Tm or more when a melting point of the first and second piezoelectric substance is defined as Tm.

The method may further include: after the performing of the heat-treatment, forming first and second conductive vias electrically connected to the first and second internal electrodes respectively, in the laminated body; and forming first and second external electrodes electrically connected to the first and second conductive vias, respectively.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a perspective view schematically showing a piezoelectric device according to an exemplary embodiment of the present disclosure;

FIG. 2 is a schematic cross-sectional view of the piezoelectric device, taken along line A-A′ of FIG. 1, and an enlarged portion of FIG. 2 shows a schematic fine structure of a piezoelectric sheet;

FIG. 3 is a perspective view schematically showing a piezoelectric device according to another exemplary embodiment of the present disclosure in which a vibrating plate is added; and

FIG. 4 is a schematic cross-sectional view of the piezoelectric device, taken along line B-B′ of FIG. 3.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

A symbol ‘dmn’ used in the present specification refers to a piezoelectric strain constant in an n-direction when voltage is applied in an m-direction.

Specifically, a d31 refers to a piezoelectric strain constant in a 1-direction (length direction) when voltage is applied in a 3-direction (thickness direction).

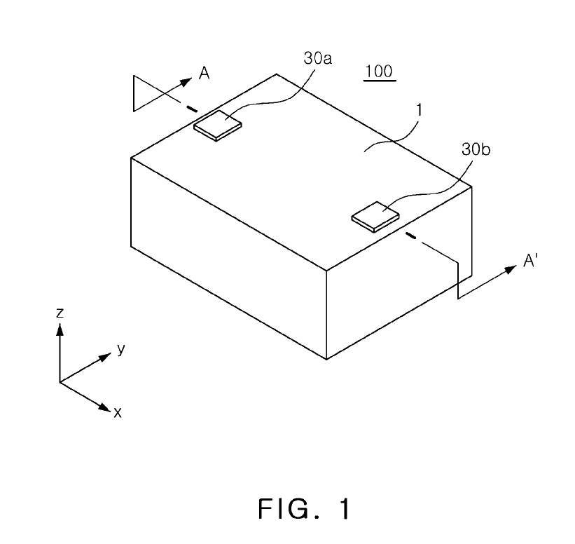

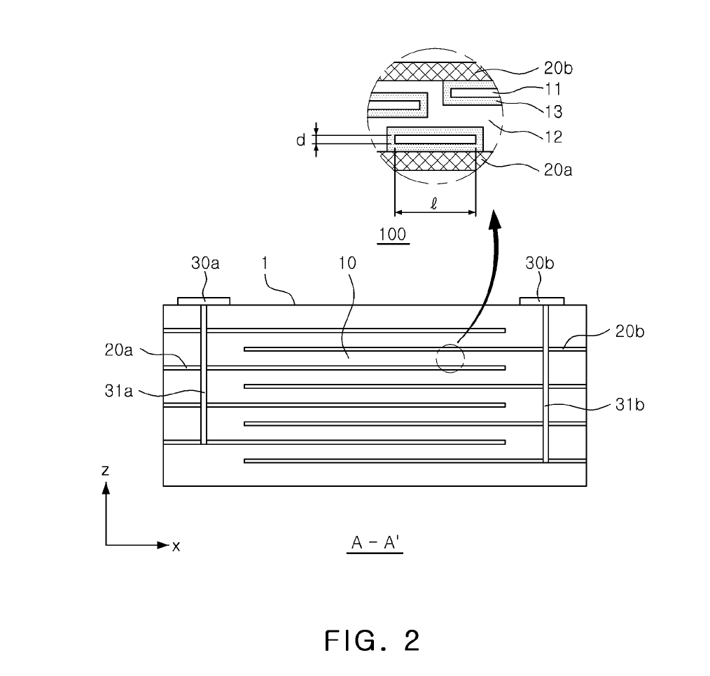

FIG. 1 is a perspective view schematically showing a piezoelectric device 100 according to an exemplary embodiment of the present disclosure, and FIG. 2 is a schematic cross-sectional view of the piezoelectric device, taken along line A-A′ of FIG. 1.

Referring to FIGS. 1 and 2, a structure of the piezoelectric device 100 according to an exemplary embodiment of the present disclosure will be described.

The piezoelectric device 100 according to an exemplary embodiment of the present disclosure may include a laminated body 1 in which a plurality of piezoelectric sheets 10 including a first piezoelectric substance 11 having a single crystal structure and a second piezoelectric substance 12 having a polycrystalline structure are laminated; first and second internal electrodes 20a and 20b interposed between the piezoelectric sheets and alternated so as to have different polarities in a laminated direction; and first and second external electrodes 30a and 30b formed on one surface of the laminated body to be electrically connected to the first and second internal electrodes 20a and 20b, respectively.

The piezoelectric sheets 10 may be formed of a material having the piezoelectric effect.

The piezoelectric effect refers to characteristics generating electrical polarization to generate a potential difference when external force is applied thereto, while generating deformation or deformative force when voltage is applied thereto.

The piezoelectric sheets 10 may be formed of at least one selected from a group consisting of crystals, tourmaline, Rochelle salts, barium titanate, and tartaric acid ethylene diamine, or a mixed material thereof, but is not limited thereto.

The first and second internal electrodes 20a and 20b may be formed using a conductive paste.

The conductive paste may be fabricated by dispersing metal powder particles having excellent conductivity such as copper (Cu), silver (Ag), or gold (Au) particles.

The first and second internal electrodes 20a and 20b may be interposed between the plurality of piezoelectric sheets 10 by being alternated so as to have different polarities.

In order to obtain the piezoelectric effect, since displacement or displacement force needs to be generated by applying electric fields having different polarities to the piezoelectric sheets 10 to thereby induce a dipole, the first and second internal electrodes 20a and 20b need to be formed to have different polarities.

That is, since the first and second internal electrodes 20a and 20b need to have different polarities, the first internal electrode 20a may be electrically connected to the first external electrode 30a and the second internal electrode 20b may be electrically connected to the second external electrode 30b.

The first and second internal electrodes 20a and 20b may be electrically connected to the first and second external electrodes 30a and 30b by first and second conductive vias 31a and 31b.

Due to the first and second conductive vias 31a and 31b, an effective area in which the piezoelectric effect is generated in the piezoelectric sheets 10 may be increased compared to a case of not using the first and second conductive vias.

In order to increase the displacement or the displacement force by improving the piezoelectric effect, a method of applying a higher level of voltage to the first and second internal electrodes 20a and 20b, a method of thinning the piezoelectric sheets 10, and a method of using a material having a high piezoelectric strain constant may be present.

However, applying a higher level of voltage to the first and second internal electrodes 20a and 20b may be restricted due to a fault of a portable electronic device caused by high levels of power and voltage.

In addition, in the case of thinning the piezoelectric sheets 10, it is difficult to reduce a thickness of the piezoelectric sheet to below a predetermined value, and a phenomenon in which metal atoms in the first and second internal electrodes 20a and 20b move through a grain boundary of the piezoelectric sheet 10 is generated, thereby decreasing reliability.

Therefore, by using the piezoelectric material having a high piezoelectric strain constant, the displacement or the displacement force of the piezoelectric device 100 may be improved without decreasing reliability.

A piezoelectric material having a single crystal structure has a value of the piezoelectric strain constant higher about 10 times or more than a case of having a polycrystalline structure.

Specifically, in comparing d31 values of a single crystal material and a polycrystalline material, it may be appreciated that the d31 value of the single crystal material is 2000 pC/N, but the d31 value of the polycrystalline material is 200 pC/N.

That is, since the single crystal material has a very high piezoelectric strain constant, the displacement or the displacement force of the piezoelectric device 100 may be increased using the very high piezoelectric strain constant.

However, since it is very difficult to fabricate the single crystal material, the single crystal material is very expensive to be fabricated, as compared to the polycrystalline material, and it is difficult to fabricate the piezoelectric sheet 10 using the single crystal material due to weak physical properties of the single crystal material.

Therefore, the piezoelectric sheet 10 may be formed by mixing the first piezoelectric substance 11 having the single crystal structure and the second piezoelectric substance 12 having the polycrystalline structure, such that the piezoelectric sheet 10 having the high piezoelectric strain constant may be obtained.

An enlarged portion of the FIG. 2 shows a schematic fine structure of the piezoelectric sheet 10 including the first piezoelectric substance 11 and the second piezoelectric substance 12.

Referring to the enlarged portion of FIG. 2, a length of the first piezoelectric substance 11 may be defined as 1 and a thickness thereof may be defined as d.

The first piezoelectric substance 11 may have a cylindrical shape or a plate shape, but is not limited thereto.

The following Table 1 shows performance and durability of the piezoelectric device 100 according to an aspect ratio (d/l) of the first piezoelectric substance 11.

TABLE 1

| Aspect | Device | | | |
|---|---|---|---|---|
| Ratio (d/l) | Performance | Workability | Reliability | Durability |
| 1/32 | Very Good | Very Good | Very Good | Very Bad |
| 2/32 | Very Good | Very Good | Very Good | Bad |
| 4/32 | Good | Very Good | Good | Good |
| 6/32 | Good | Good | Good | Good |
| 8/32 | Good | Good | Good | Good |
| 10/32 | Bad | Good | Bad | Good |
| 12/32 | Bad | Bad | Bad | Good |
| 24/32 | Bad | Bad | Bad | Very Good |

Device performance was indicated as being Good in the case in which it was 250 pC/N or more, and was indicated as being Very Good in the case in which it was 300 pC/N or more, on the basis of the d31 value.

Workability was indicated as being Bad in the case in which a value obtained by averaging an absolute value of an angle formed by the first piezoelectric substance 11 based on a laminated surface exceeded 15°, was indicated as being Good in the case in which the value was 10° to 15°, and was indicated as being Very Good in the case in which the value was below 10°, when the piezoelectric sheet 10 was formed by mixing the first piezoelectric substance 11 and the second piezoelectric substance 12 and then a fine structure of the piezoelectric sheet 10 was imaged using a scanning electron microscope (SEM).

Reliability was evaluated using results obtained by measuring the time taken for a short-circuit to occur after the mixing of the first piezoelectric substance 11 and the second piezoelectric substance 12 to form the piezoelectric sheet 10, forming electrodes on both surfaces of the piezoelectric sheet 10 using a conductive paste including silver (Ag), and then applying voltage to the electrodes.

Specifically, reliability was indicated as being Very Good in the case in which the short-circuit did not occur, was indicated as being Good in the case in which the short-circuit occurred after 4000 hours or more, and was indicated as being Bad in other cases.

Durability was indicated as being Very Bad in the case in which a breakage ratio of the first piezoelectric substance 11 exceeded 60%, was indicated as being Bad in the case in which the ratio was greater than 50% but below 60%, was indicated as being Good in the case in which the ratio was 40% to 50%, and was indicated as being Very Good in the case in which the ratio was below 40%, when the piezoelectric sheet 10 was formed by mixing the first piezoelectric substance 11 and the second piezoelectric substance 12 and then a fine structure of the piezoelectric sheet 10 was imaged using a scanning electron microscope (SEM).

Referring to Table 1, the aspect ratio (d/l) of the first piezoelectric substance 11 may be 1/8 (=4/32) to 1/4 (=8/32).

Specifically, in the case in which the aspect ratio (d/l) of the first piezoelectric substance 11 exceeds 1/4, a contact area between the first piezoelectric substance 11 and the second piezoelectric substance 12 is decreased, such that the d31 value is decreased.

In addition, in the case in which the aspect ratio (d/l) of the first piezoelectric substance 11 exceeds 10/32, the average of the absolute value of the angle formed by the first piezoelectric substance 11 and the laminated surface exceeds 15°.

In the case in which the average of the absolute value of the angle formed by the first piezoelectric substance 11 and the laminated surface exceeds 15°, the first piezoelectric substance 11 is not uniformly aligned, such that the piezoelectric effect may be decreased.

On the other hand, in the case in which the aspect ratio (d/l) of the first piezoelectric substance 11 is below 1/8, damage such as breakage or cracking of the first piezoelectric substance 11 may be generated during a process of fabricating the piezoelectric sheet 10.

That is, the first piezoelectric substance 11 is broken or cracked, such that a rate in which the aspect ratio of the first piezoelectric 11 exceeds 1/4 may be increased.

Therefore, device performance and workability may be decreased.

As a result, in order to improve device performance and workability and secure durability, the aspect ratio (d/l) of the first piezoelectric substance 11 may be 1/8 to 1/4.

Due to the miniaturization and thinning of the device in the recent times, a phenomenon in which metal atoms contained in the internal electrode move through a grain boundary of the piezoelectric sheet 10 has been generated.

When a positive voltage and a negative voltage are applied to the first and second internal electrodes 20a and 20b, respectively, formed on both surfaces of the piezoelectric sheet 10, Ag+ moves from the first internal electrode 20a to which the positive voltage is applied to the second internal electrode 20b to which the negative voltage is applied, and is reduced in the second internal electrode 20b to thereby be grown in the grain boundary the piezoelectric sheet 10.

In the case in which the growth of Ag as described is continued, the first internal electrode 20a and the second internal electrode 20b are electrically short-circuited through the grown Ag to thereby cause a failure of the piezoelectric device.

However, since the piezoelectric device 100 according to the exemplary embodiment of the present disclosure may include the first piezoelectric substance 11 having the single crystal structure, the first piezoelectric substance 11 having the single crystal structure may serve to cut off a grain boundary of the second piezoelectric substance 12 having the polycrystalline structure.

That is, by cutting the grain boundary connected from the first internal electrode 20a to the second internal electrode 20b, or extending the grain boundary, the movements of Ag+ may be blocked.

Specifically, referring to Table 1, in the case in which the aspect ratio (d/l) of the first piezoelectric substance 11 is 1/4 or less, the first piezoelectric substance 11 may serve to cuff off the grain boundary, such that reliability of the piezoelectric device may be improved.

According to an exemplary embodiment of the present disclosure, the piezoelectric device may further include a piezoelectric shell 13 enclosing the first piezoelectric substance 11.

The piezoelectric shell 13 may be formed by compressing and heating the first piezoelectric substance 11 and the second piezoelectric substance 12 and rearranging the second piezoelectric substance 12 in a circumference of the first piezoelectric substance 11.

Specifically, since the first piezoelectric substance 11 has the single crystal structure, the first piezoelectric substance 11 and the second piezoelectric substance 12 having the polycrystalline structure may be compressed and subjected to a heat treatment at a temperature of 0.5 Tm or more when a melting temperature of the first and second piezoelectric substances 11 and 12 is defined as Tm, such that the second piezoelectric substance 12 in the circumference of the first piezoelectric substance 11 may be recrystallized to thereby form the piezoelectric shell 13.

Since the piezoelectric shell 13 does not have a complete single crystal structure as in the first piezoelectric substance 11, but has a crystal direction as in the first piezoelectric substance 11 due to the re-crystallization, it has a d31 value higher than the second piezoelectric substance 11.

Specifically, the d31 value of the piezoelectric shell 13 may be 200 pC/N to 700 pC/N.

The following Table 2 shows results obtained by measuring a d31 value of the piezoelectric sheet 10 according to the content of the first piezoelectric substance 11 and a d31 value of the piezoelectric sheet in the case in which the piezoelectric shell 13 was formed, after the piezoelectric sheet 10 was fabricated using the first piezoelectric substance 11 having an aspect ratio of 1/4.

TABLE 2

| | Case in which | Case in which | |
|---|---|---|---|
| | piezoelectric | piezoelectric | |
| | shell was not | shell was formed | Difference |
| | formed (A) | (B) | Value (B − A) |
| Content (%) | d31 (pC/N) | d31 (pC/N) | d31 (pC/N) |
| 0 | 200 | — | — |
| | | (Piezoelectric | |
| | | shell could not be | |
| | | formed) | |
| 2 | 232.4 | 262.1 | 29.7 |
| 3 | 248.6 | 408.7 | 160.1 |
| 5 | 281 | 482.3 | 201.3 |
| 10 | 362 | 585 | 223 |
| 15 | 443.3 | 687.3 | 244 |
| 20 | 524 | 724.5 | 200.5 |
| 25 | 605 | 772 | 167 |
| 30 | 686 | 807.9 | 121.9 |
| 31 | 702.2 | 762.2 | 60 |
| 32 | 718.4 | 745.8 | 27.4 |
| 33 | 734.6 | 759.5 | 24.9 |

Referring to Table 2, it may be appreciated that in the case in which the piezoelectric shell was not formed, as the content of the first piezoelectric substance 11 was increased, the d31 value of the piezoelectric sheet 10 was increased.

It may be appreciated that in the case in which the piezoelectric shell was formed, a range of an increase of the d31 value was gradually increased in accordance with an increase in the content of the first piezoelectric substance 11, and then was decreased.

Specifically, when the content of the first piezoelectric substance 11 was 2%, a difference in the d31 values between the case in which the piezoelectric shell was formed and the case in which the piezoelectric shell was not formed was 29.7 pC/N. However, when the content of the first piezoelectric substance 11 was 3%, the difference was significantly increased to 160.1 pC/N.

In addition, when the content of the first piezoelectric substance 11 was 31%, the difference in the d31 values between the case in which the piezoelectric shell was formed and the case in which the piezoelectric shell was not formed was decreased to 60 pC/N.

That is, in the case in which the content of the first piezoelectric substance 11 was 2%, since a contact area between the first piezoelectric substance 11 and the second piezoelectric substance 12 was small and a re-crystallized amount of the second piezoelectric substance 12 was small, the amount of the piezoelectric shell 13 generated was small and the range of an increase in the d31 value was small.

As the amount of the first piezoelectric substance is increased, the contact area between the first piezoelectric substance 11 and the second piezoelectric substance 12 may be significantly increased, such that the range of the increase in the d31 value may also be increased.

However, in the case in which the amount of the first piezoelectric substance 11 is continuously increased, the amount of the second piezoelectric substance 12 may be decreased, such that the contact area between the first piezoelectric substance 11 and the second piezoelectric substance 12 may be reduced, thereby decreasing the range of the increase in the d31 value, again.

That is, in order to significantly increase the d31 value by forming the piezoelectric shell 13, the content of the first piezoelectric substance 11 may be 3% to 30%.

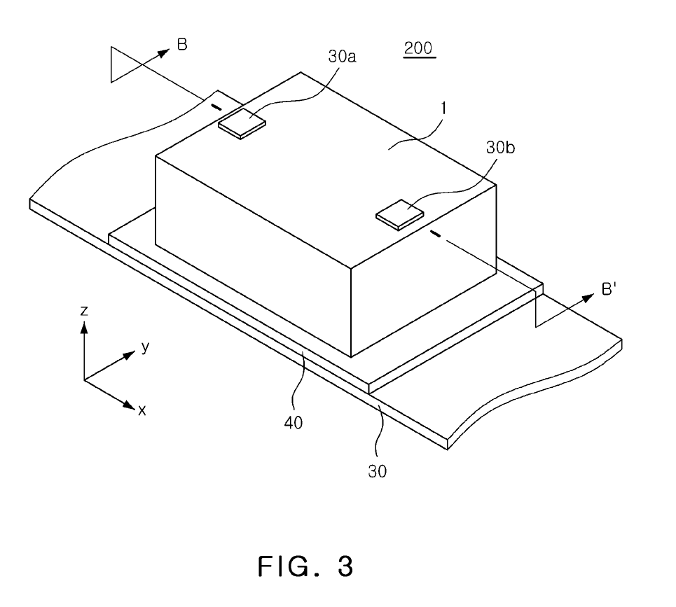

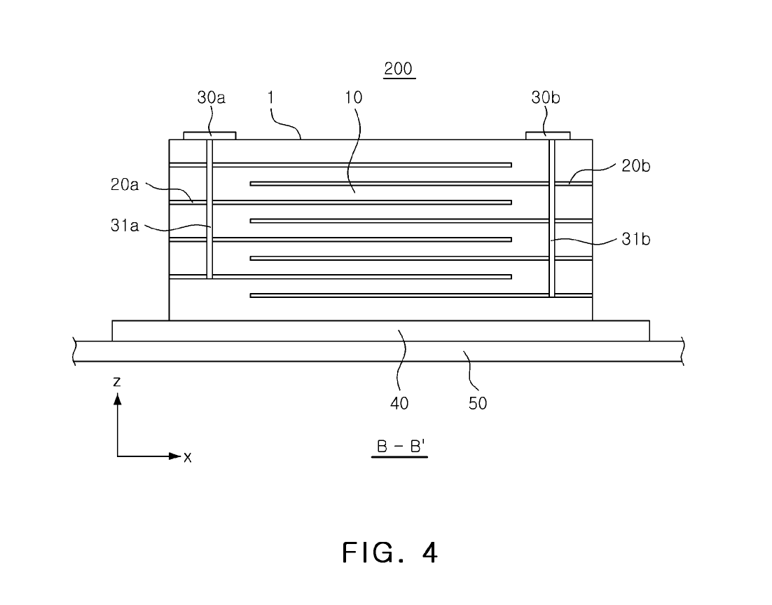

FIG. 3 is a perspective view schematically showing a piezoelectric device 200 according to another exemplary embodiment of the present disclosure to which a vibrating plate 40 is attached and FIG. 4 is a schematic cross-sectional view of the piezoelectric device, taken along line B-B′ of FIG. 3.

The piezoelectric device 200 may be formed to be attached to the vibrating plate 40.

In the case in which a positive voltage and a negative voltage are applied to the first and second external electrodes 30a and 30b, respectively, of the piezoelectric device 200, displacement or displacement force may be generated in the piezoelectric sheet 10 by the piezoelectric effect.

In the case in which a length of the piezoelectric device 200 is decreased in a length direction (x-direction), the vibrating plate 40 may be bent in a downwardly convex manner.

Thereafter, in the case in which a negative voltage and a positive voltage are applied to the first and second external electrodes 30a and 30b, respectively, of the piezoelectric device 200, or the applied voltage is removed, the length of the piezoelectric device 200 is increased in the length direction (x-direction) and the vibrating plate 40 has an upwardly convex form or a flat form.

By repeating a process of alternately applying the positive voltage and the negative voltage to the first and second external electrodes 30a and 30b, respectively, or a process of applying and removing the voltage, the vibrating plate 40 may be repeatedly bent and unbent, thereby generating vibrations.

Therefore, since displacement of the piezoelectric device 200 in the length direction (x-direction) significantly affects such a change in the vibrating plate 40 as compared to displacement of the piezoelectric device 200 in a thickness direction (z-direction), the d31 value (a piezoelectric strain constant in the x-direction at the time of an application of voltage in the z-direction) significantly affects performance of the piezoelectric device 200 as compared to a d33 value (a piezoelectric strain constant in the z-direction at the time of an application of voltage in the z-direction).

The vibrating plate 40 may be attached to one surface of a substrate 50 to thereby generate vibrations in an electronic device.

The substrate 50 may be a printed circuit board 50, but is not limited thereto.

Hereinafter, a method of fabricating a piezoelectric device according to an exemplary embodiment of the present disclosure will be described.

A method of fabricating a piezoelectric device according to an exemplary embodiment of the present disclosure may include preparing the first piezoelectric substance 11 having a single crystal structure and a second piezoelectric substance 12 having a polycrystalline structure; mixing the first and second piezoelectric substances 11 and 12; preparing a plurality of green sheets by compressing the mixed first and second piezoelectric substances 11 and 12; printing first and second internal electrodes 20a and 20b on the green sheets using a conductive paste; preparing a laminated body 1 by laminating and compressing the green sheets having the first and second internal electrodes 20a and 20b printed thereon; and performing a heat-treatment on the laminated body 1.

First, the preparing of the first piezoelectric substance 11 may be performed such that an aspect ratio (d/l) of the first piezoelectric substance 11 may be 1/8 to 1/4.

That is, the first piezoelectric substance 11 may be prepared in a cylindrical shape or a plate shape in which a length thereof is greater than 4 times or more and equal to or less than 8 times a diameter (thickness) thereof.

The second piezoelectric substance 12 may be formed of powder.

In the case in which the second piezoelectric substance 12 is formed of powder, as a mean particle diameter is reduced, compactness may be increased, such that performance of the piezoelectric device may be improved.

Next, the first piezoelectric substance 11 and the second piezoelectric substance 12 may be mixed with each other.

The plurality of green sheets may be fabricated by compressing the mixed first and second piezoelectric substances 11 and 12, and the first and second internal electrodes 20a and 20b may be formed on the green sheet using the conductive paste.

The plurality of green sheets are laminated and compressed, and then are cut to have a desired piezoelectric device size, such that the laminated body 1 may be formed.

Thereafter, the laminated body 1 may be sintered or heat-treated, such that the piezoelectric shell 13 enclosing the first piezoelectric substance 11 may be formed by performing the heat-treatment.

In general, a temperature at which re-crystallization is generated is significantly lower than the melting temperature Tm of a material. The heat-treatment may be performed at a temperature of 0.5 Tm or more when a melting point of the first and second piezoelectric substances 11 and 12 is defined as temperature Tm.

Therefore, since the piezoelectric shell 13 may be formed by the re-crystallization at 0.5 Tm, a relatively low temperature rather than a significantly high temperature such as the melting point, the performance of the piezoelectric device may be improved at low cost.

According to another exemplary embodiment of the present disclosure, the method of fabricating the piezoelectric device may further include, after performing the heat-treatment, forming the first and second conductive vias 31a and 31b electrically connected to the first and second internal electrodes 20a and 20b, respectively, in the laminated body 1; and forming the first and second external electrodes 30a and 30b electrically connected to the first and second conductive vias 31a and 31b, respectively.

As set forth above, the piezoelectric sheet according to exemplary embodiments of the present disclosure may include the first piezoelectric substance having the single crystal structure, such that it may have a high d31 value.

Further, since the first piezoelectric substance may have an aspect ratio (d/l) of 1/8 to 1/4, a phenomenon in which the first piezoelectric substance is broken may be prevented to thereby allow for an improvement in durability, and a contact interface between the second piezoelectric substance having the polycrystalline structure and the first piezoelectric substance having the single crystal structure may be increased.

That is, the contact interface between the first and second piezoelectric substances may be increased, such that a phenomenon in which metal atoms contained in the internal electrode move through the grain boundary of the second piezoelectric substance may be prevented, thereby allowing for improvements in reliability.

While exemplary embodiments have been shown and described above, it will be apparent to those skilled in the art that modifications and variations could be made without departing from the spirit and scope of the present disclosure as defined by the appended claims.

What is claimed is:

1. A piezoelectric sheet, comprising:
a first piezoelectric substance having a single crystal structure; and
a second piezoelectric substance having a polycrystalline structure,
wherein the first piezoelectric substance has an aspect ratio (d/l) of 1/8 to 1/4.

2. The piezoelectric sheet of claim 1, further comprising a piezoelectric shell enclosing the first piezoelectric substance.

3. The piezoelectric sheet of claim 2, wherein the piezoelectric shell has a crystal direction the same as that of the first piezoelectric substance.

4. The piezoelectric sheet of claim 2, wherein the piezoelectric shell has a d31 value of 200 pC/N to 700 pC/N.

5. The piezoelectric sheet of claim 1, wherein the first piezoelectric substance has a content of 3% to 30%.

6. A piezoelectric device, comprising:
a laminated body in which a plurality of piezoelectric sheets including a first piezoelectric substance having a single crystal structure and a second piezoelectric substance having a polycrystalline structure are laminated;
first and second internal electrodes interposed between the piezoelectric sheets and alternating so as to have different polarities in a laminated direction; and
first and second external electrodes formed on one surface of the laminated body to be electrically connected to the first and second internal electrodes,
wherein the first piezoelectric substance has an aspect ratio (d/l) of 1/8 to 1/4.

7. The piezoelectric device of claim 6, further comprising: a piezoelectric shell enclosing the first piezoelectric substance.

8. The piezoelectric device of claim 7, wherein the piezoelectric shell has a crystal direction the same as that of the first piezoelectric substance.

9. The piezoelectric device of claim 7, wherein the piezoelectric shell has a d31 value of 200 pC/N to 700 pC/N.

10. The piezoelectric device of claim 6, wherein the first piezoelectric substance has a content of 3% to 30%.

11. The piezoelectric device of claim 6, further comprising: a vibrating plate attached to a bottom surface of the laminated body.

12. A method of fabricating a piezoelectric device, the method comprising:
preparing a first piezoelectric substance having a single crystal structure and a second piezoelectric substance having a polycrystalline structure;
mixing the first and second piezoelectric substances;
preparing a plurality of green sheets by compressing the mixed first and second piezoelectric substances;
printing first and second internal electrodes on the green sheets using a conductive paste;
preparing a laminated body by laminating and compressing the green sheets having the first and second internal electrodes printed thereon; and
performing a heat-treatment on the laminated body,
wherein the first piezoelectric substance has an aspect ratio (d/l) of 1/8 to 1/4.

13. The method of claim 12, wherein by the performing of the heat-treatment, a piezoelectric shell enclosing the first piezoelectric substance is formed.

14. The method of claim 12, wherein the heat-treatment is performed at a temperture of 0.5 Tm or more when a melting point of the first and second piezoelectric substance is defined as Tm.

15. The method of claim 12, further comprising: after the performing of the heat-treatment,
forming first and second conductive vias electrically connected to the first and second internal electrodes respectively, in the laminated body; and
forming first and second external electrodes electrically connected to the first and second conductive vias, respectively.
